(19) United States
(12) Patent Application Publication
(10) Pub. No.: US 2017/0117475 A1
(43) Pub. Date: Apr. 27, 2017

(54) ORGANIC LIGHT-EMITTING DISPLAY DEVICE, APPARATUS FOR DEPOSITING ORGANIC LAYER, AND METHOD OF MANUFACTURING ORGANIC LIGHT-EMITTING DISPLAY DEVICE BY USING THE SAME

(71) Applicant: Samsung Display Co., Ltd., Yongin-si (KR)

(72) Inventors: Minsoo KIM, Yongin-si (KR); Mugyeom Kim, Yongin-si (KR); Valeriy Prushinskiy, Yongin-si (KR); Muhyun Kim, Yongin-si (KR); Dongkyu Lee, Yongin-si (KR); Byungkook Lee, Yongin-si (KR); Jaesoo Ha, Yongin-si (KR)

(21) Appl. No.: 15/130,061

(22) Filed: Apr. 15, 2016

(30) Foreign Application Priority Data
Oct. 27, 2015 (KR) 10-2015-0149735

(51) Int. Cl. H01L 51/00; H01L 27/32; H01L 51/56

(52) U.S. Cl. CPC H01L 51/0013; H01L 51/56; H01L 27/3211; H01L 2227/323

(57) ABSTRACT

An apparatus for depositing an organic layer includes a deposition unit including a deposition assembly spaced apart from a substrate. The deposition assembly includes a deposition source configured to heat a deposition material, a deposition source nozzle unit installed on the deposition source, a plurality of pattern sheets facing the deposition source nozzle unit, and a source shutter disposed between the deposition source and the plurality of pattern sheets. The deposition source nozzle unit includes a deposition nozzle. The plurality of pattern sheets include at least one of a plurality of first patterning slits and a plurality of second patterning slits. The source shutter is configured to allow the deposition material to pass through one of the plurality of pattern sheets depending on a relative location between the deposition source and the substrate.

### CROSS-REFERENCE TO RELATED APPLICATION

This application claims priority from and the benefit of Korean Patent Application No. 10-2015-0149735, filed on Oct. 27, 2015, which is hereby incorporated by reference for all purposes as if fully set forth herein.

### BACKGROUND

Field

Exemplary embodiments relate to a device, an apparatus, and a method. More particularly, exemplary embodiments relate to an organic light-emitting display device, an apparatus for depositing an organic layer for an organic light-emitting display device, and a method of manufacturing an organic light-emitting display device by using the apparatus.

Discussion of the Background

Organic light-emitting display devices have advantages of a wide viewing angle, excellent contrast, and fast response speeds. Due to these advantages, the organic light-emitting display device is positioned as a next-generation display device.

Typically, organic light-emitting display devices have a layer that is formed by closely attaching a fine metal mask (FMM) having an opening of a pattern which is the same as or similar to a pattern of the layer to be formed on a substrate, and depositing the layer on the substrate.

However, the method of using a fine metal mask has a limitation of being unsuitable for manufacturing a large scale organic light-emitting display device with a large scale mother-glass because warping of a mask is generated by the weight of a large-sized mask and distortion of a pattern may be generated by the warping. This is contradictory to a current trend requiring a high definition pattern.

Furthermore, it takes considerable time to perform the processes of aligning and closely attaching a substrate and a fine metal mask, performing deposition, and then separating the substrate from the fine metal mask. Therefore, the manufacturing takes a long time and production efficiency is low.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an organic light-emitting display device, an apparatus for depositing an organic layer, and a method of manufacturing an organic light-emitting display device by using the same.

Additional aspects will be set forth in the detailed description which follows, and, in part, will be apparent from the disclosure, or may be learned by practice of the inventive concept.

An exemplary embodiment discloses an apparatus for depositing an organic layer with a deposition unit including a deposition assembly spaced apart from a substrate. The deposition assembly includes a deposition source configured to heat a deposition material, a deposition source nozzle unit installed on the deposition source, a plurality of pattern sheets facing the deposition source nozzle unit, and a source shutter disposed between the deposition source and the plurality of pattern sheets. The deposition source nozzle unit includes a deposition nozzle. The plurality of pattern sheets include at least one of a plurality of first patterning slits and a plurality of second patterning slits. The source shutter is configured to allow the deposition material to pass through one of the plurality of pattern sheets depending on a relative location between the deposition source and the substrate.

Another exemplary embodiment discloses a method of manufacturing an organic light-emitting display device. The method includes fixing a substrate to a movement portion at a loading portion, transferring the movement portion inside a chamber by using a first transfer portion of the apparatus installed to pass through the chamber, heating a deposition material from a deposition source nozzle unit of a deposition assembly, passing the heated deposition material through a pattern sheet opened by a source shutter, depositing the deposition material on different regions of the substrate while the substrate moves relative to the deposition assembly that is disposed inside the chamber spaced, separating the substrate having the deposition material from the movement portion at an unloading portion, and transferring the movement portion to the loading portion by using a second transfer portion installed to pass through the chamber. The pattern sheet faces the deposition source nozzle unit and includes at least one of a plurality of first patterning slits that allows the deposition material to pass to a first region from among different regions of the substrate and a plurality of second patterning slits that allows the deposition material to pass to a second region from among the different regions of the substrate.

An exemplary embodiment also discloses an organic light-emitting display device, including a base substrate, a thin film transistor disposed on the base substrate, a plurality of pixel electrodes disposed on the thin film transistor, a plurality of organic layers disposed on the plurality of pixel electrodes, and a plurality of opposite electrodes disposed on the plurality of organic layers. The thin film transistor includes a semiconductor active layer, a gate electrode insulated from the semiconductor active layer, a source electrode contacting the semiconductor active layer, and a drain electrode contacting the semiconductor active layer. At least one of the plurality of organic layers disposed on the base substrate is formed by using the apparatus for depositing an organic layer described above.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan conceptual view illustrating an apparatus for depositing an organic layer according to an exemplary embodiment.

FIG. 2 is a perspective cross-sectional view illustrating a portion of the apparatus for depositing the organic layer illustrated in FIG. 1.

FIG. 3 is a cross-sectional view illustrating a portion of a deposition portion of the apparatus for depositing the organic layer illustrated in FIG. 1.

FIG. 4 is a conceptual view illustrating a deposition source and a pattern sheet of the apparatus for depositing the organic layer illustrated in FIG. 1.

FIG. 5 is a perspective view illustrating a deposition source, a pattern sheet, and a source shutter of the apparatus for depositing the organic layer illustrated in FIG. 4.

FIG. 6 is a plan conceptual view illustrating a pattern sheet of FIG. 5 according to an exemplary embodiment.

FIG. 7 is a plan conceptual view illustrating a pattern sheet of FIG. 5 according to an exemplary embodiment.

FIG. 8 is a plan conceptual view illustrating a pattern sheet of FIG. 7 according to an exemplary embodiment.

FIG. 9 is a plan conceptual view illustrating a pattern sheet of FIG. 5 according to an exemplary embodiment.

FIG. 10 is a plan conceptual view illustrating a pattern sheet of FIG. 9 according to an exemplary embodiment.

FIGS. 11, 12, 13, 14, and 15 are plan conceptual views illustrating an operation of a source shutter during a deposition process.

FIG. 16 is a cross-sectional view illustrating a portion of an organic light-emitting display device manufactured by using the apparatus for depositing the organic layer illustrated in FIG. 1.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” “right,” left,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

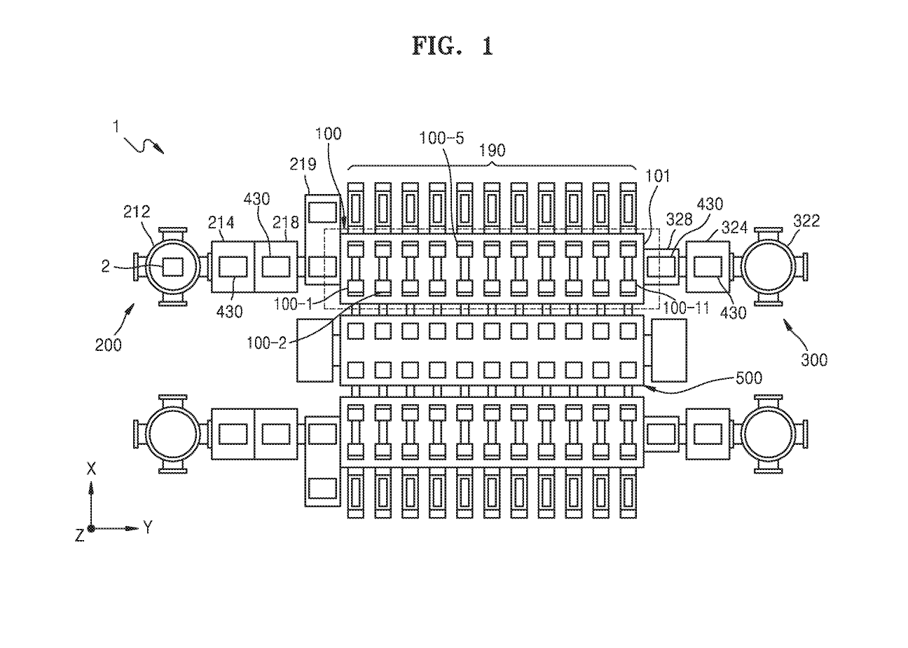

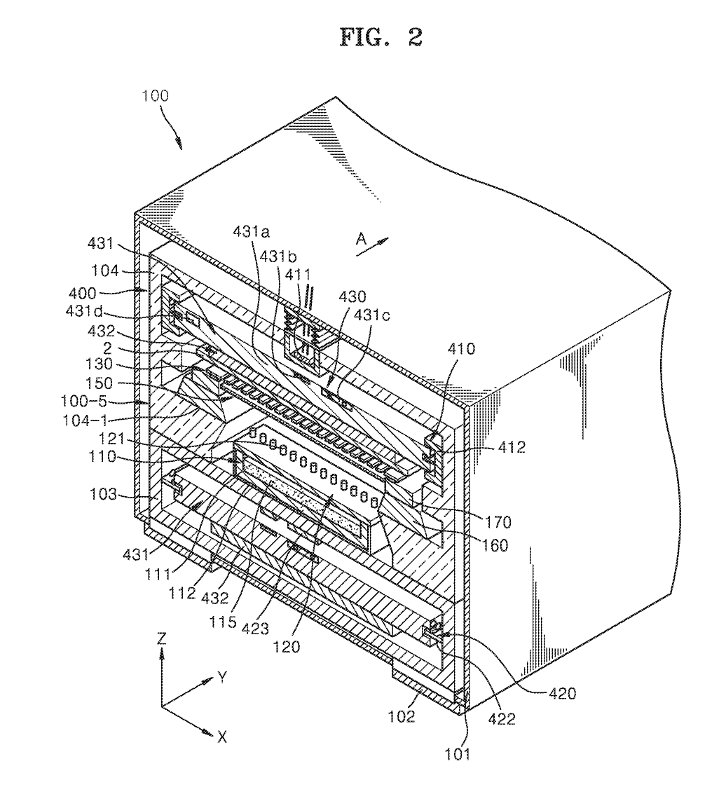

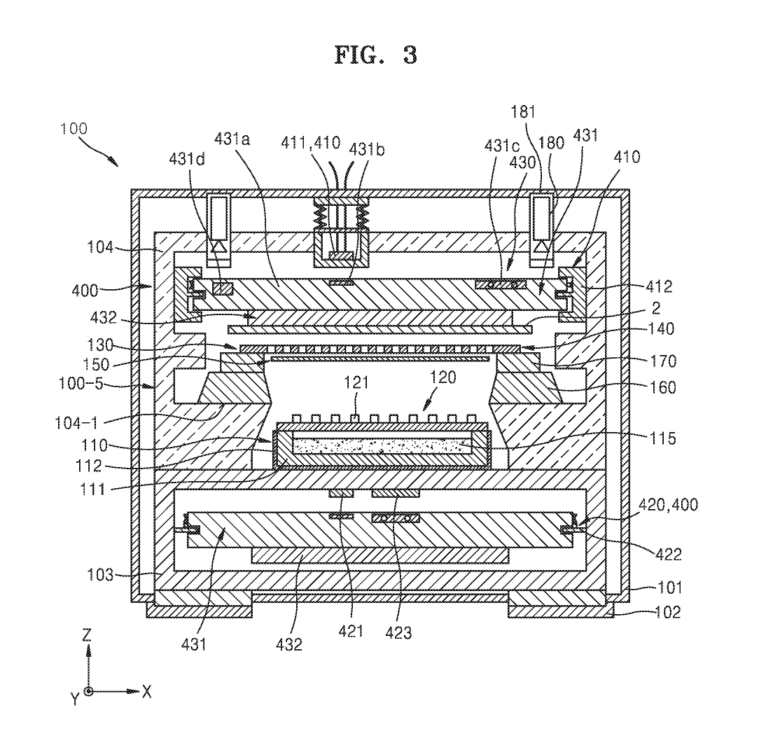

FIG. 1 is a plan conceptual view illustrating an apparatus for depositing an organic layer according to an exemplary embodiment. FIG. 2 is a perspective cross-sectional view illustrating a portion of the apparatus for depositing the organic layer illustrated in FIG. 1. FIG. 3 is a cross-sectional view illustrating a portion of a deposition portion 100 of the apparatus for depositing the organic layer illustrated in FIG. 1.

Referring to FIGS. 1, 2 and 3, an apparatus 1 for depositing the organic layer includes the deposition portion 100, a loading portion 200, an unloading portion 300, and a transfer portion 400.

The loading portion 200 may include a first rack 212, an introduction chamber 214, a first reversion chamber 218, and a buffer chamber 219.

A plurality of substrates 2, before deposition is performed, may be stacked on the first rack 212, and an introduction robot provided to the introduction chamber 214 may take the substrate 2 from the first rack 212, may put the substrate 2 on a movement portion 430 transferred from a second transfer portion 420, and then may transfer the movement portion 430 on which the substrate 2 has been attached to the first reversion chamber 218.

The first reversion chamber 218 may be provided adjacent to the introduction chamber 214, and a first reversion robot located at the first reversion chamber 218 may reverse the movement portion 430 and may mount the movement portion 430 to a first transfer portion 410 of the deposition portion 100.

Referring to FIG. 1, the introduction robot of the introduction chamber 214 puts the substrate 2 on an upper surface of the movement portion 430. Under this state, the movement portion 430 may be transferred to the reversion chamber 218. When the first reversion robot of the reversion chamber 218 reverses the reversion chamber 218, the substrate 2 may be positioned such that the substrate 2 faces downward in the deposition portion 100.

The construction of the unloading portion 300 is different from the construction of the above-described loading portion 200. That is, a second reversion robot in a second reversion chamber 328 may reverse the substrate 2 and the movement portion 430 that have passed through the deposition portion 100 and may transfer the same to a carrying-out chamber 324. A carrying-out robot may take out the substrate 2 and the movement portion 430 from the carrying-out chamber 324. The carrying-out robot may separate the substrate 2 from the movement portion 430 and may stack the substrate 2 on a second rack 322. The movement portion 430 separated from the substrate 2 may be sent back to the loading portion 200 via the second transfer portion 420.

However, exemplary embodiments are not limited thereto, and the substrate 2 may be fixed on a lower surface of the movement portion 430 when the substrate 2 is initially fixed to the movement portion 430, and then transferred to the deposition portion 100. In this case, for example, the first reversion robot of the first reversion chamber 218 and the second reversion robot of the second reversion chamber 328 are not required.

The deposition portion 100 may include at least one chamber 101 for deposition. According to an exemplary embodiment illustrated in FIGS. 1 and 2, the deposition portion 100 includes a chamber 101, and a plurality of deposition assemblies 100-1, 100-2, . . . , 100-n are disposed inside the chamber 101. According to an exemplary embodiment illustrated in FIG. 1, eleven deposition assemblies including a first deposition assembly 100-1, a second deposition assembly 100-2, a third deposition assembly 100-3, a fourth deposition assembly 100-4, a fifth deposition assembly 100-5, a sixth deposition assembly 100-6, a seventh deposition assembly 100-7, an eighth deposition assembly, 100-8, a ninth deposition assembly 100-9, a tenth deposition assembly 100-10, and an eleventh deposition assembly 100-11 are installed inside the chamber 101, but a number of the deposition assemblies is variable depending on a deposition material and a deposition condition. The chamber 101 may be maintained at a vacuum state while deposition is performed.

As illustrated in FIG. 1, the movement portion 430 to which the substrate 2 has been fixed may be moved to at least the deposition portion 100 by the first transfer portion 410. Specifically, the movement portion 430 may be sequentially moved to the loading portion 200, the deposition portion 100, and the unloading portion 300. The movement portion 430 separated from the substrate 2 by the unloading portion 300 may be sent back to the loading portion 200 by a second transfer portion 420.

The first transfer portion 410 may be provided to pass through the chamber 101 when passing through the deposition portion 100. The second transfer portion 420 may be provided to transfer the movement portion 430 from which the substrate 2 has been separated.

Here in apparatus 1, the first transfer portion 410 and the second transfer portion 420 may be formed up and down, and the movement portion 430 that completes deposition while passing through the first transfer portion 410 may be separated from the substrate 2 by the unloading portion 300, and then may be sent back to the loading portion 200 via the second transfer portion 420 formed below, so that efficiency of space utilization improves.

The deposition portion 100 of FIG. 1 may further include a deposition source replacement portion 190 on one side of each deposition assembly 100-n (n is a natural number of 1 to 11). Though not illustrated in the drawing in detail, the deposition source replacement portion 190 may be formed in a cassette type and drawn from each deposition assembly 100-n (n is a natural number of 1 to 11). Therefore, replacement of a deposition source 110 (see FIG. 3) of the deposition assembly 100-1 may be easy.

FIG. 1 illustrates that a series of sets for configuring the apparatus 1 for depositing the organic layer including the loading portion 200, the deposition portion 100, the unloading portion 300, and the transfer portion 400 may be provided, side by side, as two sets. That is, it may be understood that a total of two sets of the apparatus 1 for depositing the organic layer may be provided to the upper portion and the lower portion of FIG. 1.

In this case, a patterning slit sheet replacement portion 500 may be further provided between the two apparatuses 1 for depositing the organic layer. That is, the patterning slit sheet replacement portion 500 may be provided between the two apparatuses 1 for depositing the organic layer to allow the two apparatuses 1 for depositing the organic layer to use the patterning slit sheet replacement portion 500 in common, so that efficiency of space utilization may improve compared with the case where each apparatus 1 for depositing the organic layer includes the patterning slit sheet replacement portion 500.

Referring to FIGS. 2 and 3, the deposition portion 100 of the apparatus 1 for depositing the organic layer may include at least one deposition assembly 100-5 and a transfer portion 400.

A configuration of the entire deposition portion 100 is described below.

The chamber 101 may be formed in a box shape whose inside is empty, and includes at least one deposition assembly 100-5 and the transfer portion 400 therein. A foot 102 may be formed such that the foot 102 is fixed on the ground, a lower housing 103 may be formed on the foot 102, and an upper housing 104 may be formed above the lower housing 103. Also, the chamber 101 may be formed to receive both the lower housing 103 and the upper housing 104 therein. In this case, a connection portion between the lower housing 103 and the chamber 101 may be sealed, so that the inside of the chamber 101 may be completely blocked from outside.

The lower housing 103 and the upper housing 104 may be formed on the foot 102 fixed on the ground, so that the lower housing 103 and the upper housing 104 may maintain their fixed locations even when the chamber 101 contracts or expands repeatedly. Thus, the lower housing 103 and the upper housing 104 may serve as a reference frame inside the deposition portion 100.

A deposition assembly 100-5 and the first transfer portion 410 of the transfer portion 400 may be formed inside the upper housing 104. The second transfer portion 420 of the transfer portion 400 may be formed inside the lower housing 103. Also, while the movement portion 430 circulates between the first transfer portion 410 and the second transfer portion 420, deposition may be performed successively.

A configuration of the deposition assembly 100-5 may be described below.

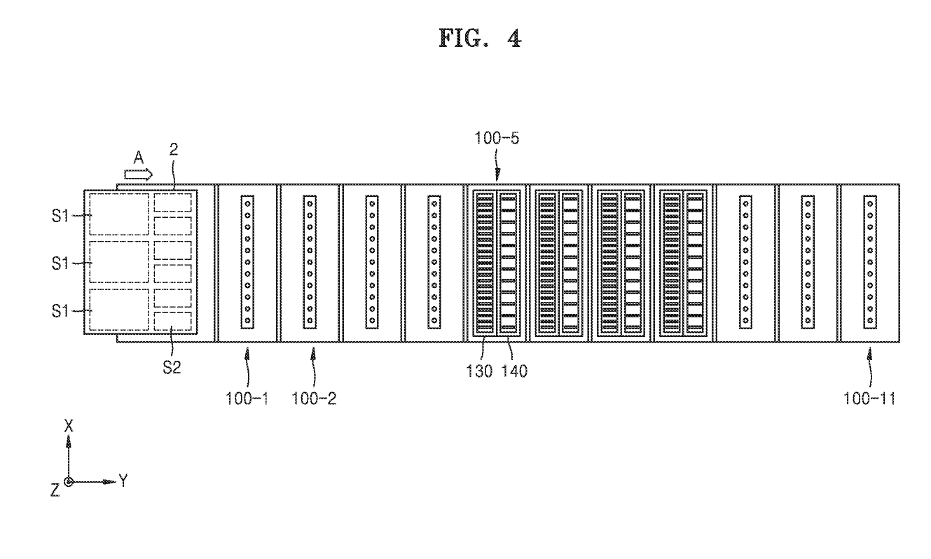

Each deposition assembly 100-5 may include the deposition source 110, a deposition source nozzle unit 120, a plurality of pattern sheets 130 and 140, a plurality of source shutters 150, a first stage 160, and a second stage 170. Here, the various configurations of FIGS. 3 and 4 may be disposed inside the chamber 101 where an appropriate vacuum level is maintained. By applying the appropriate vacuum level, the direction of a deposition material 115 may be secured.

The substrate 2, which is a deposition object, may be disposed inside the chamber 101. The substrate 2 may be a substrate for a flat panel display device, and a large scale substrate that may manufacture a flat panel display device of about 40 inches or more may be applied.

Here, while the substrate 2 moves relative to the deposition assembly 100-5, deposition is performed.

In detail, in a conventional fine metal mask (FMM) deposition method, the size of an FMM should be the same as the size of a substrate. Therefore, when the size of a substrate increases, an FMM should correspondingly increase. However, manufacturing an FMM, especially a large FMM, is difficult and it is also difficult to elongate the FMM and align the FMM in a fine pattern.

To resolve this problem, deposition may be performed while the substrate 2 moves relative to the deposition assembly 100-5. In other words, while the substrate 2 facing the deposition assembly 100-5 moves along a Y-axis, deposition may be performed successively. That is, while the substrate 2 moves in an arrow A direction, deposition may be performed in a scanning manner.

Here, although the drawing illustrates that while the substrate 2 moves in a Y-axis direction inside the chamber 101, deposition is performed, the spirit of the inventive concept is not limited thereto, and the substrate 2 may be fixed and the deposition assembly 100-5 itself may move in the Y-axis direction and perform deposition.

Therefore, the deposition assembly 100-5 may make the first pattern sheet 130 and the second pattern sheet 140 much smaller compared with the conventional FMM. That is, in the case of the deposition assembly 100-5, since the substrate 2 performs deposition successively, that is, in a scanning manner while moving along the Y-axis direction, a length in at least one of the X-axis direction and the Y-axis direction of the first pattern sheet 130 and/or the second pattern sheet 140 may be formed much smaller than the length of the substrate 2.

As described above, since the first pattern sheet 130 and the second pattern sheet 140 may be made much smaller than the conventional FMM, manufacturing the first pattern sheet 130 and the second pattern sheet 140 is easier than the conventional FFM. That is, small first pattern sheet 130 and second pattern sheet 140 are advantageous compared with the FMM deposition method in all processes including an etching operation of the first pattern sheet 130 and the second pattern sheet 140, fine elongation, welding, movement, and washing operations. Also, when the organic light-emitting display device 10 is large, small-sized pattern sheets are even more advantageous.

For deposition to be performed while the deposition assembly 100-5 moves relative to the substrate 2, the deposition assembly 100-5 may be spaced apart from the substrate 2, which will be described later.

The deposition source 110 in which a deposition material 115 is received and heated may be disposed on a side facing the substrate 2 inside the chamber. When the deposition material 115 received inside the deposition source 110 evaporates, deposition may be performed on the substrate 2.

In detail, the deposition source 110 may include a crucible 111 filled with the deposition material 115 and a heater 112 for evaporating the deposition material 115 that fills the inside of the crucible 111. For example, the evaporated deposition material 115 may flow through the deposition source nozzle unit 120.

The deposition source nozzle unit 120 may disposed on one side of the deposition source 110, specifically, on the side of the deposition source 110 that faces the substrate 2. Here, in the deposition assembly 100-5, deposition nozzles may be formed differently in depositing a common layer and a pattern layer.

The plurality of pattern sheets 130 and 140 may be provided between the deposition source 110 and the substrate 2. The pattern sheets 130 and 140 may be described below.

The deposition material 115 that evaporates inside the deposition source 110 may pass through the deposition source nozzle unit 120 and the plurality of pattern sheets 130 and 140 such that the evaporated deposition material 115 is directed toward the substrate 2, which is a deposition object. In this case, the plurality of pattern sheets 130 and 140 may be manufactured by using etching, which is the same method as a manufacturing method of the conventional FMM. In particular, the plurality of pattern sheets 130 and 140 may be manufactured using a stripe type mask. However, the plurality of pattern sheets 130 and 140 are not limited to being manufactured through an etching process. The plurality of pattern sheets 130 and 140 may be manufactured by using a electro-forming method or a laser patterning method.

As described above, the deposition assembly 100-5 may perform deposition while moving relative to the substrate 2. For the deposition assembly 100-5 to move relative to the substrate 2, the plurality of pattern sheets 130 and 140 are spaced apart from the substrate 2.

In detail, the conventional FMM deposition method performs a deposition process by closely attaching a mask on a substrate so that a shadow may not be generated on the substrate. However, where the mask contacts the substrate, a defect occurs due to the contact between the substrate and the mask. Also, since the mask cannot be moved relative to the substrate, the mask should be formed in the same size as that of the substrate. Therefore, when the organic light-emitting display device 10 is large, the size of the mask should increase, but forming a large scale mask is difficult.

To resolve this problem, the deposition assembly 100-5 according to an exemplary embodiment allows the plurality of pattern sheets 130 and 140 to be spaced apart from the substrate 2, which is a deposition object, with an interval.

According to an exemplary embodiment, the deposition is performed while the plurality of pattern sheets 130 and 140 move relative to the substrate 2, manufacturing of the plurality of pattern sheets 130 and 140 is easy. Also, a defect due to a contact between the substrate 2 and the plurality of pattern sheets 130 and 140 may be prevented. Also, since a time for closely attaching the plurality of pattern sheets 130 and 140 on the substrate 2 during the process is not required, the amount of time required for manufacturing decreases.

Next, a specific disposition of each component inside the upper housing 104 is described below.

First, the deposition source 110 and the deposition source nozzle unit 120 are disposed on the bottom portion of the upper housing 104. Also, seating portions 104-1 may protrude at both sides of the deposition source 110 and the deposition source nozzle unit 120. Also, the first stage 160, the second stage 170, and the plurality of pattern sheets 130 and 140 may be sequentially disposed on the seating portions 104-1.

Here, the first stage 160 may be movable in the X-axis direction and the Y-axis direction and may align the first pattern sheet 130 and the second pattern sheet 140 in the X-axis direction and the Y-axis direction. That is, the first stage 160 may be formed to move in the X-axis direction and the Y-axis direction with respect to the upper housing 104 by including a plurality of actuators.

The second stage 170 may be formed to be movable in a Z-axis direction and aligns the first pattern sheet 130 and the second pattern sheet 140 in the Z-axis direction. That is, the second stage 170 may be formed to move in the Z-axis direction with respect to the first stage 160 by including a plurality of actuators.

The plurality of pattern sheets 130 and 140 may be disposed on the second stage 170. As described above, the plurality of pattern sheets 130 and 140 may be formed on the first stage 160 and the second stage 170 to allow the plurality of pattern sheets 130 and 140 to be movable in the Y-axis direction and the Z-axis direction, so that alignment between the substrate 2 and the plurality of pattern sheets 130 and 140 may be performed.

Furthermore, the upper housing 104, the first stage 160, and the second stage 170 may simultaneously guide a movement path of the deposition material 115 so that the deposition material 115 discharged via deposition source nozzles 121 may not be dispersed. That is, a path of the deposition material 115 is sealed by the upper housing 104, the first stage 160, and the second stage 170, so that movement of the deposition material 115 in the X-axis direction and the Y-axis direction may be simultaneously guided.

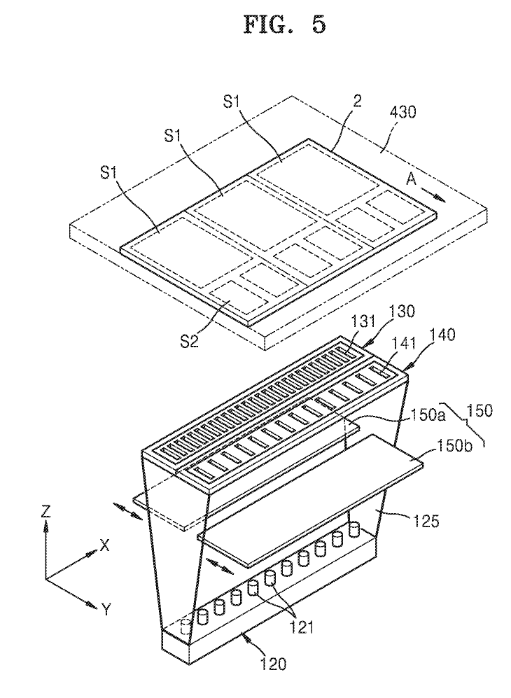

The source shutter 150 may be provided between the deposition source 110 and the plurality of pattern sheets 130 and 140. The source shutter 150 may be configured by relative driving of a first shutter 150a and a second shutter 150b (shown in FIG. 5). Although not shown in the drawing, a plurality of source shutter drivers that move the source shutter 150 may be further provided inside the deposition portion 100. In this case, each of the plurality of source shutter driver may include a general motor and a gear assembly, and include a cylinder performing a linear motion in one direction. However, the above-described source shutter driver is not limited thereto and may include all apparatuses that allow the source shutter 150 to perform a linear motion.

In detail, the source shutter 150 may allow the deposition material 115 to pass through one of the plurality of pattern sheets 130 and 140 so that the deposition material 115 may be deposited on at least one of a first region S1 and a second region S2 on the substrate 2 depending on a relative location of the deposition source 110 and the substrate 2.

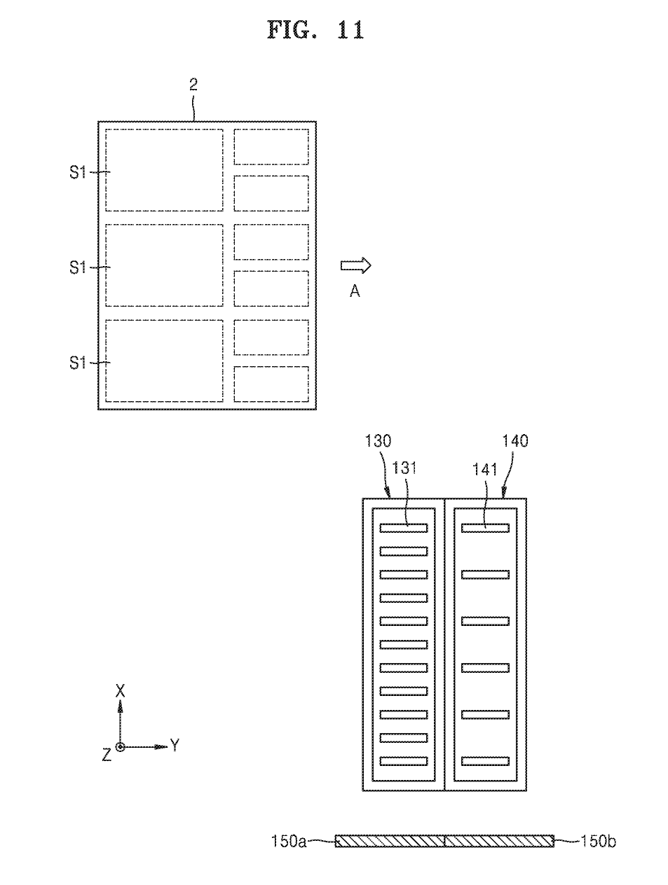

In detail, in the case where the source shutter 150 opens one pattern sheet 130, the other pattern sheet 140 may be blocked. On the contrary, in the case where the other pattern sheet 140 is opened, the one pattern sheet 130 may be blocked. The driving of the source shutter 150 is described below with reference to FIGS. 11, 12, 13, 14, and 15.

Although not shown in the drawing, a blocking member (not shown) for preventing an organic material from being deposited on a non-layer forming region of the substrate 2 may be further provided inside the deposition portion 100. The blocking member (not shown) may be formed to move together with the substrate 2, so that the non-layer forming region of the substrate 2 is hidden. Thus, the deposition of an organic material on the non-layer forming region of the substrate 2 is prevented even without a separate structure.

The transfer portion 400 that transfers the substrate 2, which is a deposition object, is described below. Referring to FIGS. 2 and 3, the transfer portion 400 may include the first transfer portion 410, the second transfer portion 420, and the movement portion 430.

The first transfer portion 410 may transfer the movement portion 430 including a carrier 431 and an electrostatic chuck 432 coupled thereto. The substrate 2 may be attached on the movement portion 430 in-line so that an organic layer may be deposited on the substrate 2 by the deposition assembly 100-5.

After a first deposition is completed on the substrate 2 while the substrate 2 passes through the deposition portion 100, the second transfer portion 420 sends back the movement portion 430 from which the substrate 2 has been separated from the unloading portion 300 to the loading portion 200. The second transfer portion 420 may include a coil 421, a roller guide 422, and a charging track 423.

The movement portion 430 may include the carrier 431 transferred along the first transfer portion 410 and the second transfer portion 420, and the electrostatic chuck 432 which may be coupled on one surface of the carrier 431 and on which the substrate 2 is attached.

Each component of the transfer portion 400 is described below.

First, the carrier 431 of the movement portion 430 is described below.

The carrier 431 may include a main body portion 431a, a magnetic rail 431b, a contactless power supply (CPS) 431c, a power unit 431d, and a guide groove (not shown).

The main body portion 431a may form a base portion of the carrier 431, and may include a magnetic substance such as iron. The carrier 431 may maintain a state spaced apart by a predetermined degree from a guide portion 412 by using magnetic force between the main body portion 431a of the carrier 431 and a magnetic levitation bearing (not shown).

Guide grooves (not shown) may be formed in both sides of the main body portion 431a, and a guide protrusion (not shown) of the guide portion 412 may be received inside the guide groove.

A magnetic rail 431b may be formed along a central line of a progression direction of the main body portion 431a. The magnetic rail 431b of the main body portion 431a couples to a coil 411, which will be described below, to form a linear motor. The carrier 431 may be transferred in a direction A by the linear motor.

In the main body portion 431a, the CPS 431c and the power unit 431d may be formed on one side of the magnetic rail 431b. The power unit 431d may be a battery for providing power so that the electrostatic chuck 432 may chuck and maintain the substrate 2. The CPS 431c may wirelessly charge the power unit 431d.

In detail, the charging track 423 formed on the second transfer portion 420, which will be described below, may be connected with an inverter (not shown). When the carrier 431 is transferred inside the second transfer portion 420, a magnetic field is formed between the charging track 423 and the CPS 431c, so that the charging track 423 supplies power to the CPS 431c. Also, the power supplied to the CPS 431c may charge the power unit 431d.

Meanwhile, the electrostatic chuck 432 may include an electrode to which power is applied. The electrostatic chuck 432 may be buried inside a main body portion 431a, which may include a ceramic material. When a high voltage is applied to the electrode, the main body portion 431a may attach the substrate 2 on the surface of the electrostatic chuck 432.

Next, driving of the movement portion 430 is described below.

The magnetic rail 431b of the main body portion 431a may couple to the coil 411 to form a driver. Here, the driver may be a linear motor. The linear motor may be a device having a very high location determination degree because a frictional coefficient is small and a location error does not nearly occur compared with the conventional sliding guide system. As described above, the linear motor may include the coil 411 and the magnetic rail 431b. The magnetic rail 431b may be disposed in a line on the carrier 431. Multiple coils 411 may be disposed with a predetermined interval inside the chamber 101 to face the magnetic rail 431b.

Since the magnetic rail 431b, not the coil 411, may be disposed on the carrier 431, which is a moving object, the carrier 431 may be driven even when power is not applied to the carrier 431. Here, the coil 411 may be formed inside an atmosphere box and thus installed under the atmospheric state. The magnetic rail 431b may be attached on the carrier 431, so that the carrier 431 may move inside the vacuum chamber 101.

The deposition assembly 100-5 of the apparatus 1 for depositing the organic layer may further include a camera 180 for alignment. In detail, the camera 180 may align a mark formed on the first pattern sheet 130 and the second pattern sheet 140 and a mark formed on the substrate 2 in real-time. Here, the camera 180 may be provided to readily secure a field of vision inside the vacuum chamber 101 in which deposition is performed. For this purpose, the camera 180 may be formed inside a camera receiving portion 181 and installed under the atmospheric state.

Next, the plurality of pattern sheets 130 and 140 disposed on the deposition assembly 100-5 may be described below with reference to FIGS. 4 and 5.

FIG. 4 is a conceptual view illustrating the disposition of a deposition source and a pattern sheet of the apparatus for depositing the organic layer illustrated in FIG. 1. FIG. 5 is a perspective view illustrating the disposition of a deposition source, a pattern sheet, and a source shutter of the apparatus for depositing the organic layer illustrated in FIG. 4.

Referring to FIGS. 4 and 5, the plurality of pattern sheets 130 and 140 may include the first pattern sheet 130 and the second pattern sheet 140. Each of the first pattern sheet 130 and the second pattern sheet 140 may be disposed to face the deposition source nozzle unit 120. Also, the first pattern sheet 130 and the second pattern sheet 140 may include at least one of a plurality of first patterning slits 131 that allow the deposition material 115 to pass to the first region S1 of the substrate 2 and a plurality of second patterning slits 141 that allow the deposition material 115 to pass to the second region S2 of the substrate 2. The second region S2 may have a size different from the size of the first region S1 of the substrate 2.

Although FIGS. 4 and 5 illustrate the plurality of first patterning slits 131 formed in the first pattern sheet 130 and the plurality of second patterning slits 141 formed in the second pattern sheet 140, exemplary embodiments are not limited thereto. Exemplary embodiments include many variations of patterning slits 131, 141 in the first pattern sheet 130 and the second pattern sheet 140.

Referring to FIG. 5, the deposition source 110, the deposition source nozzle unit 120 coupled thereto, the first pattern sheet 130, and the second pattern sheet 140 may be connected with each other by using a connection member 125.

That is, the deposition source 110, the deposition source nozzle unit 120, the first pattern sheet 130, and the second pattern sheet 140 may be connected and integrally formed with each other. Here, the connection members 125 may guide a movement path of the deposition material so that the deposition material radiated via the deposition source nozzles 121 may not be dispersed. Particularly, the connection member 125 may completely seal a space between the deposition source 110, the deposition source nozzle unit 120, the first pattern sheet 130, and the second pattern sheet 140. For example, connection member 125 may enclose the space between the deposition source 110, the deposition source nozzle unit 120, the first pattern sheet 130, and the second pattern sheet 140

Although the drawing illustrates the connection member 125 is formed in only a left/right direction (i.e., at the opposing ends of the X-axis) of the deposition source 110, the deposition source nozzle unit 120, the first pattern sheet 130, and the second pattern sheet 140 and guides only an X-axis direction of the deposition material 115, this is description merely a convenient illustration. The spirit of exemplary embodiments is not limited thereto, and the connection member 125 may be formed in a box-shaped closed type and may simultaneously guide the movements of the deposition material in the X-axis direction and the Y-axis direction.

The first pattern sheet 130 and the second pattern sheet 140 may be formed to have a length corresponding to the substrate 2 in a direction crossing a movement direction A of the substrate 2, that is, the X-axis direction. This is one of various exemplary embodiments of the first pattern sheet 130 and the second pattern sheet 140. As described above, depending on driving of the source shutter 150 that opens one of the first pattern sheet 130 and the second pattern sheet 140, the deposition material 115 that passes through the first patterning slits 131 may be deposited on the second region S2 of the substrate 2, and the deposition material 115 that passes through the second patterning slits 141 may be deposited on the first region S1 of the substrate 2.

A method of depositing an organic layer by using the apparatus 1 for depositing the organic layer is described below with reference to FIGS. 1, 2, 3, 4, and 5.

After the loading portion 200 may fix the substrate 2 to the movement portion 430. The movement portion 430 may be mounted on the first transfer portion 410 via the first reversion chamber 218. Although the first transfer portion 410 enters the inside of the chamber 101 and sequentially passes through the first deposition assembly 100-1, second deposition assembly 100-2, third deposition assembly 100-3, fourth deposition assembly 100-4, fifth deposition assembly 100-5, sixth deposition assembly 100-6, seventh deposition assembly 100-7, eighth deposition assembly 100-8, ninth deposition assembly 100-9, tenth deposition assembly 100-10, and eleventh deposition assembly 100-11, some or all of the deposition assemblies 100-1, 100-2, 100-3, 100-4, 100-5, 100-6, 100-7, 100-8, 100-9, 100-10, and 100-11 may form corresponding organic layers.

In this case, the formed organic layers may be different from each other, and the organic layer may include an organic emission layer. The formed organic layers may include a hole injection layer (HIL) a hole transport layer (HTL), an electron transport layer (ETL), and an electron injection layer (EIL). The HIL, HTL, ETL, and EIL may form a common layer, and the organic emission layer may form a pattern layer. The organic emission layer may be different depending on color to be implemented.

When the deposition of the organic layer is complete, the substrate 2 may be separated from the movement portion 430 by the unloading portion 300 and removed from the deposition assembly 100. After that, an opposite electrode is formed on the organic layer, and then the organic layer is sealed by using a thin film encapsulation substrate or an encapsulation substrate, so that the organic light-emitting display device 10 may be manufactured.

A method of forming the pattern layer is described below. While performing a linear motion depending on the motion of the first transfer portion 410, the substrate 2 may enter the deposition assembly 100-n (n is a natural number ranging from 1 to 11).

When the deposition source 110 heats the deposition material 115 by evaporating or sublimating the deposition material 115, the heated deposition material 115 that has passed through the first pattern sheet 130 and the second pattern sheet 140 may be deposited on the substrate 2. This deposition process may be performed by selectively opening the first pattern sheet 130 and the second pattern sheet 140 by driving the source shutter 150. A method of performing a deposition process by driving the source shutter 150 is described below with reference to FIGS. 11, 12, 13, 14, and 15.

A movement path of the deposition material 115 may be guided so that the deposition material 115 flowing through the deposition source nozzles 121 may not be dispersed by the connection member 125 connecting the deposition source 110, the deposition source nozzle unit 120 coupled thereto, the first pattern sheet 130, and the second pattern sheet 140 with each other.

Although the drawings illustrate the connection member 125 may be formed in only a left/right direction (i.e., at opposing ends of the X-axis) of the deposition source 110, the deposition source nozzle unit 120, the first pattern sheet 130, and the second pattern sheet 140 and may guide only the X-axis direction of the deposition material 115. This is for convenience of description, and the spirit of exemplary embodiments is not limited thereto. The connection member 125 may be formed in a box-shaped closed type and may simultaneously guide the movement of the deposition material in the X-axis direction and the Y-axis direction.

Since the deposition material may sequentially pass through the first pattern sheet 130 and the second pattern sheet 140 depending on the transfer of the substrate 2, the deposition of the organic layer may be successively performed.

The substrate 2 may be formed in various sizes. In this case, when another layer is formed on the substrate 2 after deposition of the organic layer on the substrate 2 is completed, multiple first regions S1 and multiple second regions S2 may be provided on the substrate 2. The first regions S1 and the second regions of the substrate may become one organic light-emitting display device 10.

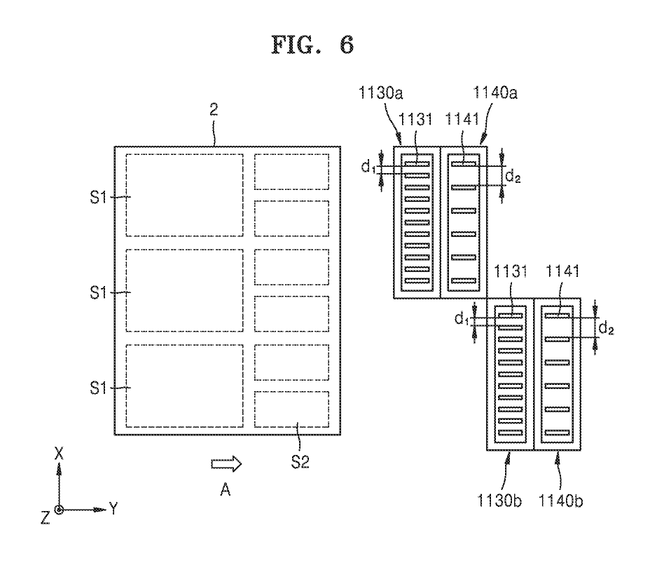

A deposition process performed by driving the source shutter 150 is described below with reference to FIGS. 11, 12, 13, 14, and 15. Next, various exemplary embodiments of the first pattern sheet 130 and the second pattern sheet 140 are described below with reference to FIGS. 6, 7, 8, 9, and 10.

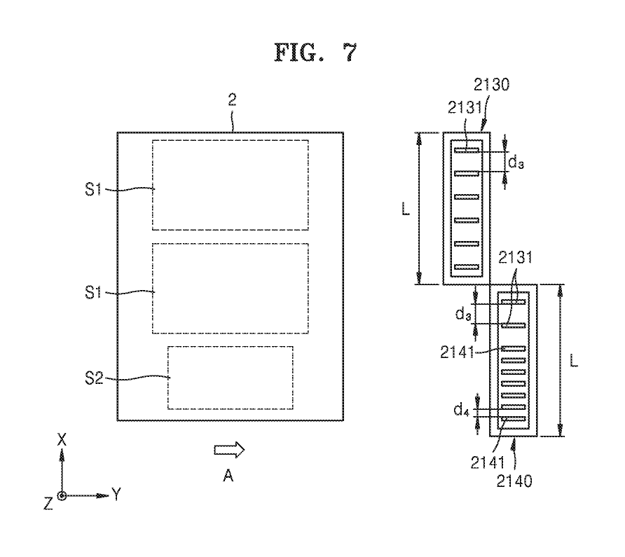

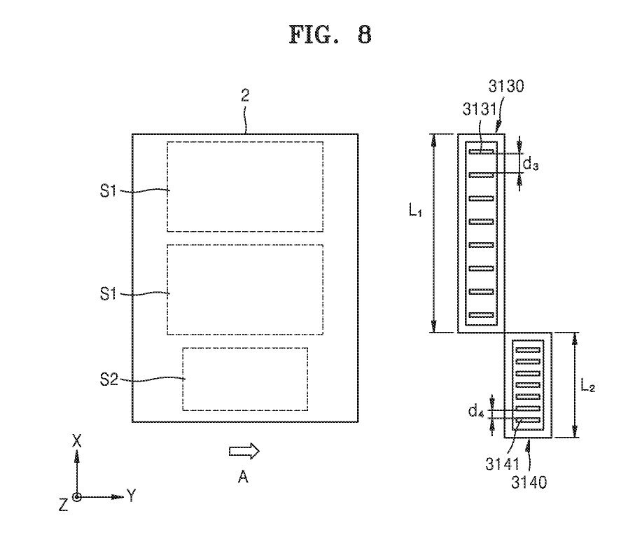

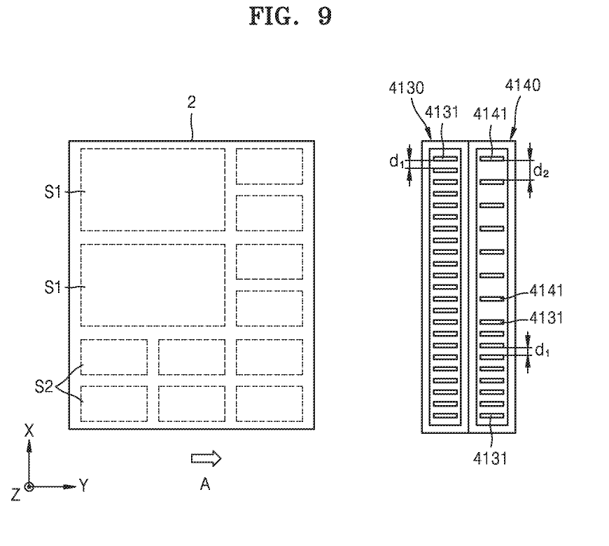

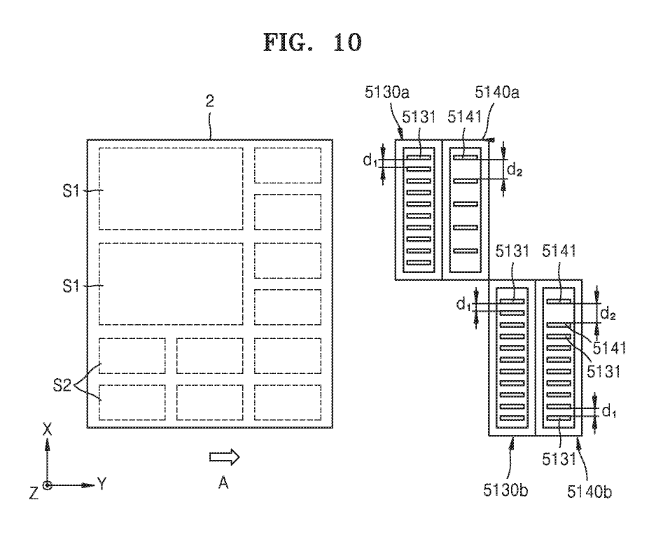

FIG. 6 is a plan conceptual view illustrating a pattern sheet illustrated in FIG. 5 according to another exemplary embodiment. FIG. 7 is a plan conceptual view illustrating a pattern sheet illustrated in FIG. 5 according to another exemplary embodiment. FIG. 8 is a plan conceptual view illustrating a pattern sheet illustrated in FIG. 7 according to an exemplary embodiment. FIG. 9 is a plan conceptual view illustrating a pattern sheet illustrated in FIG. 5 according to another exemplary embodiment. FIG. 10 is a plan conceptual view illustrating a pattern sheet illustrated in FIG. 9 according to an exemplary embodiment.

Referring to FIG. 6, first pattern sheets 1130a and 1130b and second pattern sheets 1140a and 1140b may be divided to have the same length. That is, although the drawing illustrates each of the first pattern sheet and the second pattern sheet is divided into two portions to perform deposition on the entire second region S2 and first region S1, exemplary embodiments are not limited thereto, and may be divided into three or more portions. In detail, as long as first patterning slits 1131 formed in the first pattern sheets 1130a and 1130b with respect to the X-axis direction are formed to correspond to the second region S2 of the substrate 2 and the second patterning slits 141 formed in the second pattern sheets 1140a and 1140b with respect to the X-axis direction are formed to correspond to the first region S1 of the substrate 2, the first pattern sheets 1130a and 1130b and the second pattern sheets 1140a and 1140b may be divided into multiple portions.

The first pattern sheets 1130a and 1130b and the second pattern sheets 1140a and 1140b may be disposed in zigzags with respect to an arbitrary straight line extending in the movement direction of the substrate 2. That is, one first pattern sheet 1130a and one second pattern sheet 1140a may be arranged side-by-side and disposed on the upper portion of the drawing, and another first pattern sheet 1130b and another second pattern sheet 1140b may be arranged side-by-side and disposed on the lower portion of the drawing.

The first region S1 and the second region S2 disposed side-by-side in the X-axis direction crossing the movement direction A of the substrate 2 are disposed on the substrate 2. Also, the first region S1 and the second region S2 are disposed side-by-side along the movement direction A of the substrate 2. After the deposition process is completed, the first region S1 and the second region S2 may be separated from the substrate 2 and may become a panel of an organic light-emitting display device.

Here, as described below, the first pattern sheets 1130a and 1130b are designed to be opened by the source shutter 150 and perform deposition on only the second region S2 of the substrate 2. The second pattern sheets 1140a and 1140b are designed to be opened by the source shutter 150 and perform deposition on only the first region S1 of the substrate 2. In this case, the first region S1 is formed to have an area larger than the area of the second region S2.

To make the density of the deposition material 115 deposited on the first region S1 smaller than the density of the deposition material 115 deposited on the second region S2, an interval “d1” of the first patterning slits 1131 formed in the first pattern sheets 1130a and 1130b that allow the deposition material 115 to pass toward the second region S2 may be smaller than an interval “d2” of the second patterning slits 1141 formed in the second pattern sheets 1140a and 1140b.

Next, referring to FIG. 7, one first pattern sheet 2130 and one second pattern sheet 2140 may be disposed in zigzags along an arbitrary straight line extending in the movement direction of the substrate 2. That is, the first pattern sheet 2130 may be disposed on the upper portion of the drawing, and the second pattern sheet 2140 may be disposed on the lower portion of the drawing. However, exemplary embodiments are not limited thereto, and a plurality of pattern sheets such as a third pattern sheet (not shown) and a fourth pattern sheet (not shown) may be formed and disposed side-by-side in the Y-axis direction so that the plurality of pattern sheets may not overlap along the X-axis direction.

Here, the first region S1 and the second region S2 formed in the substrate 2 may be disposed side-by-side in the X-axis direction crossing the movement direction A of the substrate 2. In the drawing, two first regions S1 and one second region S2 are formed in the X-axis direction and the first region S1. Multiple second regions S2 are not formed in the Y-axis direction, but as illustrated in FIG. 7, the first region S1 and the second region S2 may be arranged side-by-side along the X-axis direction.

According to an exemplary embodiment, the first pattern sheet 2130 illustrated in FIG. 7 includes only the first patterning slits 2131 spaced apart from each other with a predetermined interval “d3”, but the second pattern sheet 2140 includes both the first patterning slits 2131 and the second patterning slits 2141. This is a configuration for depositing the deposition material 115 with different intervals on the first region S1 and the second region S2 formed in the substrate 2. The second patterning slits 2141 having an interval “d4” smaller than the interval “d3” between the first patterning slits 2131 may be formed in a region of the second pattern sheet 2140 that overlaps the second region S2 with respect to the movement direction A of the substrate 2. According to this configuration, the deposition material 115 that has passed through the first patterning slit 2131 may be deposited with an interval corresponding to the reference letter “d3” on the first region S1, and the deposition material 115 that has passed through the second patterning slit 2141 may be deposited with an interval corresponding to the reference letter “d4” on the second region S2. While disclosed as different, in other embodiments at least some of the intervals may be the same.

Next, FIG. 8 illustrates that disposition of the first region S1 and the second region S2 formed in the substrate 2 is the same as illustrated in FIG. 7, but the lengths of the first pattern sheet 3130 and the second pattern sheet 3140 in the X-axis direction are different than the first pattern sheet 2130 and 2140. That is, the sum of the length of the first pattern sheet 3130 and the length of the second pattern sheet 3140 with reference to the X-axis direction is the same as the length of the substrate 2 as illustrated in FIG. 7, but FIG. 8 illustrates that the first pattern sheet 3130 is longer than the second pattern sheet 3140.

According to an exemplary embodiment, FIG. 8 illustrates that the first pattern sheet 3130 and the second pattern sheet 3140 are configured such that the first region S1 overlaps the first pattern sheet 3130, and the second region S2 overlaps the second pattern sheet 3140 with reference to the movement direction A of the substrate 2. According to this configuration, the first pattern sheet 3130 may include a plurality of first patterning slits 3131 spaced apart from each other with a predetermined interval “d3”, and the second pattern sheet 3140 may include a plurality of second patterning slits 3141 spaced apart from each other with an interval corresponding to the reference letter “d4” less than the reference letter “d3”.

Next, referring to FIG. 9, the second region S2 may be disposed on the right side of the substrate 2 (i.e., a first end of the substrate 2 along the Y-axis), and the first region S1 and the second region S2 may be simultaneously disposed on the left of the substrate 2 (i.e., a second end of the substrate 2 along the Y-axis that is opposite the first end). In this case, the first patterning slits 4131 spaced apart from each other with the predetermined interval “d1” may be formed in the first pattern sheet 4130 that performs deposition on only the second region S2. The second pattern sheet 4140 performs deposition on the first region S1 and the second region S2 simultaneously. Thus the second pattern sheet 4140 may include both the first patterning slits 4131 and the second patterning slits 4141. Here, the interval “d2” between the second patterning slits 4141 adjacent to each other may be greater than the interval “d1” between the first patterning slits 4131. This is because the second patterning slits 4141 is used for performing deposition on the first region S1 having an area greater than that of the second region S2.

Referring to FIG. 10, the first region S1 and the second region S2 are disposed in the substrate 2 as illustrated in FIG. 9, but first pattern sheets 5130a and 5130b and second pattern sheets 5140a and 5140b are divided to have the same length as illustrated in FIG. 6.

Here, the first pattern sheets 5130a and 5130b may be used for performing deposition on the second region S2 located on the right side of the substrate 2 and the second pattern sheets 5140a and 5140b may be used for simultaneously performing deposition on the first region S1 and the second region S2 located on the left of the substrate 2. For this purpose, first patterning slits 5131 and second patterning slits 5141 may be simultaneously formed in the second pattern sheets 5140a and 5140b. That is, the second patterning slits 5141 spaced apart from each other with a relatively wide interval corresponding to the reference letter “d2” may be formed in a region corresponding to a portion of the second pattern sheet 5140 that overlaps the first region S1 with reference to the movement direction A of the substrate 2, and the first patterning slits 5131 spaced apart from each other with a relatively narrow interval corresponding to the reference letter “d1” may be formed in a region corresponding to another portion of the second pattern sheet 5140 that overlaps the second region S2.

Next, driving of the source shutter 150 in a process in which the deposition material 115 passes through the plurality of pattern sheets 130 and 140 and is deposited on the substrate 2 is described below with reference to FIGS. 11 to 15.

FIGS. 11, 12, 13, 14, and 15 are plan conceptual views illustrating an operation of a source shutter during a deposition process.

FIGS. 11, 12, 13, 14, and 15 illustrate the configurations of the substrate 2, the first pattern sheet 130, and the second pattern sheet 140 illustrated in FIGS. 4 and 5. Thus, for brevity, thee descriptions of the configurations of the first region S1 and the second region S2 formed in the substrate 2 and the first pattern sheet 130 and the second pattern sheet 140 are omitted.

As described above, the source shutter 150 may include the first shutter 150a and the second shutter 150b. FIG. 11 illustrates a state in which the substrate 2 moves in a direction of the reference letter A but before reaching the first pattern sheet 130. In this case, since the deposition material 115 is not deposited on the substrate 2, the first shutter 150a and the second shutter 150b block the first pattern sheet 130 and the second pattern sheet 140 simultaneously so that the deposition material 115 may not pass through the first patterning slits 131 and the second patterning slits 141.

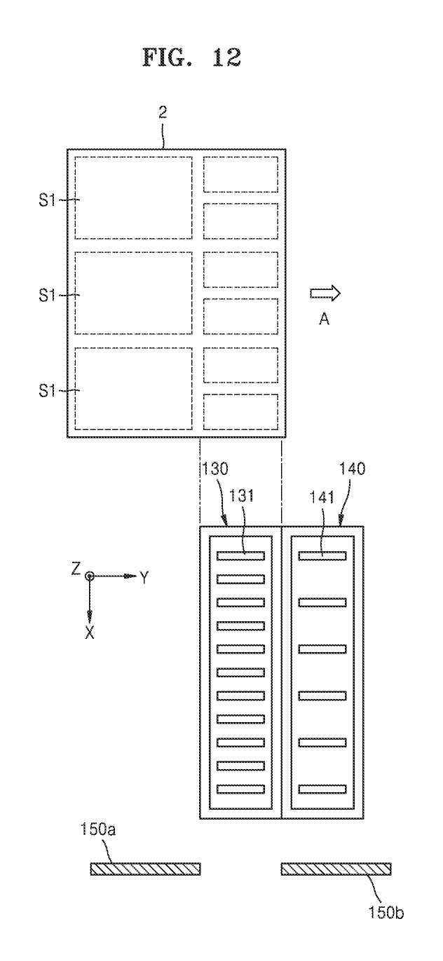

FIG. 12 illustrates that deposition is performed on the second region S2 located on the right of the substrate 2. Since the second region S2 has an area smaller than that of the first region S1, the first pattern sheet 130 including the first patterning slits 131 spaced apart from each other with a relatively narrow interval may be opened. Thus, the first shutter 150a may move away from the first pattern sheet 130 (e.g., moves to the left of the first pattern sheet 130 as shown in the drawing) and opens a space between the first pattern sheet 130 and the substrate 2 to allow the deposition material 115 to pass through the first patterning slits 131 and to be deposited on the second region S2. In other words, the first shutter 150a is moved to a position where the first shutter 150a is not aligned with the first pattern sheet 130 and does not block the deposition material 115 from passing through the first patterning slits 131. In this case, the second shutter 150b does not move (i.e., maintains its position as aligned with the second pattern sheet 140) in order to block a space between the substrate 2 and the second pattern sheet 140.

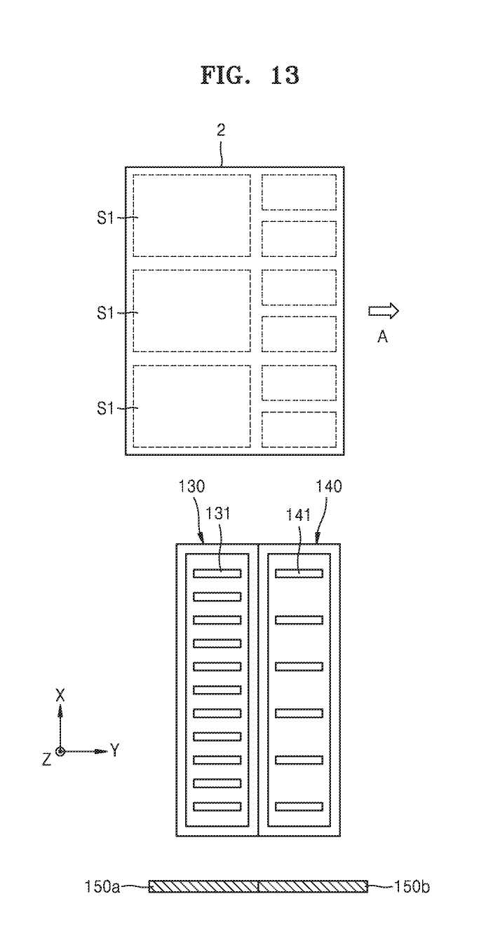

FIG. 13 illustrates a state in which after the deposition material 115 is deposited on the second region S2 of the substrate 2 via the first patterning slits 131, but before the first region S1 of the substrate 2 reaches the second pattern sheet 140. In this case, since the deposition material 115 is not deposited on the first region S1 of the substrate 2 through the first patterning slits 131, the first shutter 150a moves to the right again (i.e., moves to a position that aligned with the first pattern sheet 130) and blocks a space between the substrate 2 and the first pattern sheet 130. In addition, because the first region has not yet reached the second pattern sheet 140, the second shutter 150b remains aligned with the second pattern sheet 140.

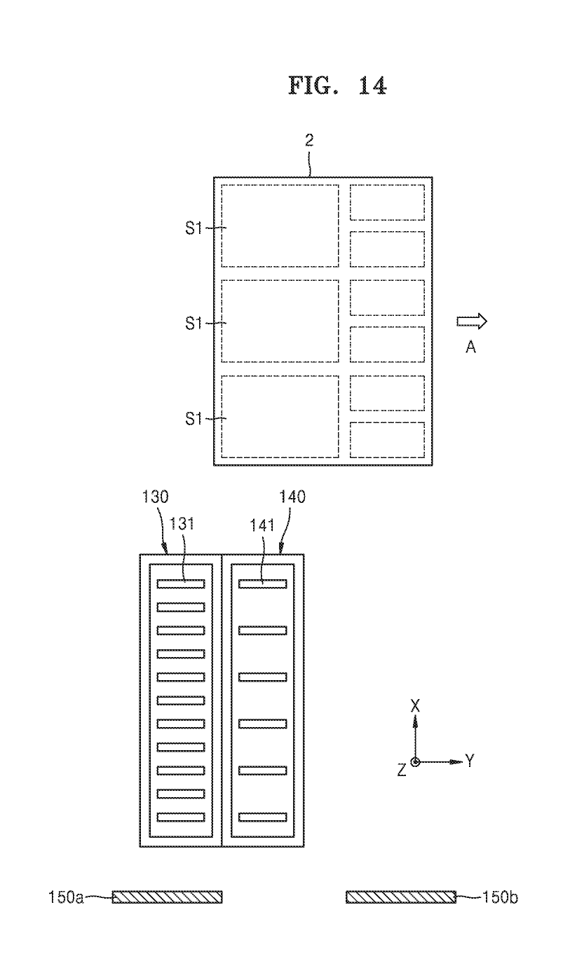

FIG. 14 illustrates that the deposition material 115 is deposited on the first region S1 of the substrate 2. Since the first region S1 has an area larger than that of the second region S2, the second pattern sheet 140 including the second patterning slits 141 spaced apart from each other with a relatively wide interval may be opened. For this purpose, the second shutter 150b moves away from the second pattern sheet 140 (e.g., moves to the right of the second pattern sheet 140 in the drawings) and opens a space between the second pattern sheet 140 and the substrate 2 to allow the deposition material 115 to pass through the second patterning slits 141 and to be deposited on the first region S1. In other words, the second shutter 150b is moved to a position where the second shutter 150b is not aligned with the second pattern sheet 140 and does not block the deposition material 115 from passing through the second patterning slits 141. In this case, the first shutter 150a does not move in order to block a space between the substrate 2 and the first pattern sheet 130.

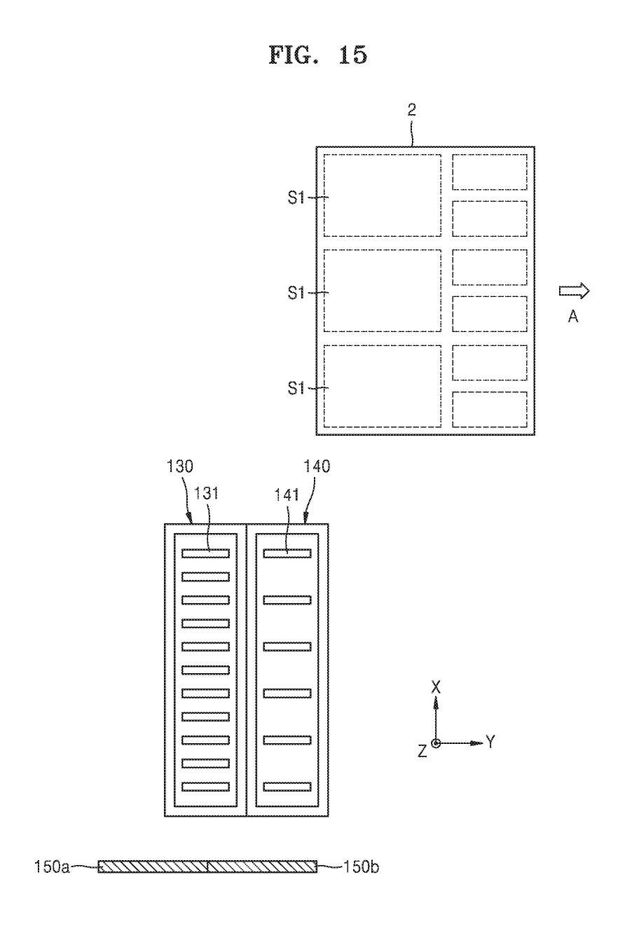

FIG. 15 illustrates that the first and second shutters 150a, 150b, the first region S1 and the second region S2 of the substrate 2 after the deposition material 115 is deposited on the first region S1 and the second region S2 of the substrate 2. That is, since the deposition material 115 does not need to be deposited on the substrate 2, the second shutter 150b that has moved to the right moves to the left again and returns to the original location, thereby blocking the first pattern sheet 130 and the second pattern sheet 140. In other words, the second shutter 150b moves to be aligned with the second pattern sheet 140.

As described above, the deposition material 115 that passes through the first patterning slits 131 and the second patterning slits 141 may be deposited on the first region S1 and the second region S2 of the substrate 2 by either blocking or opening a path that starts from the deposition source 110, passes through the plurality of pattern sheets 130 and 140, and reaches the substrate 2.

When the apparatus 1 for depositing the organic layer having the above configuration is used, display panels having various sizes may be manufactured in one substrate 2. The substrate 2 may include the plurality of first regions S1 and second regions S2. The deposition process may be simplified by using the plurality of pattern sheets 130 and 140 including at least one of the first patterning slits 131 and the second patterning slits 141 respectively having different intervals and by driving the source shutter 150 that sequentially opens the pattern sheets 130 and 140 from the upstream portion to the downstream portion with reference to the movement direction A of the substrate 2. Also, a defect rate of a display panel may be reduced through the simplification of the deposition process, and furthermore, manufacturing costs of the display panel may be reduced.

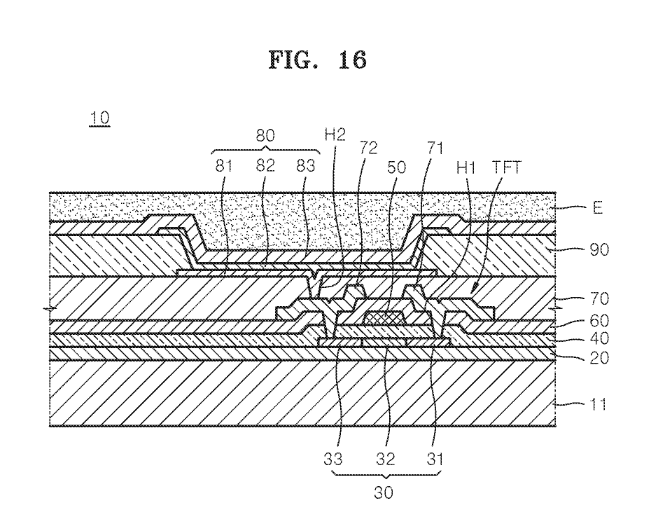

FIG. 16 is a cross-sectional view illustrating a portion of an organic light-emitting display device 10 manufactured by using the apparatus for depositing the organic layer illustrated in FIG. 1.

Referring to FIG. 16, the organic light-emitting display device 10 may include a first substrate 11 and an emission portion (not marked). Also, the organic light-emitting display device 10 may include a thin film encapsulation layer E formed above the emission portion or a second substrate (not shown). In this case, the first substrate 11 may include the same material as that of the substrate 2. The first substrate 11 may be formed by cutting the substrate 2 into a plurality of units after the organic light-emitting display device 10 is manufactured. Also, since the second substrate is the same as or similar to that used for a general organic light-emitting display device, the description of the second substrate is omitted for brevity. Also, for convenience of description, the case where the organic light-emitting display device 10 includes the thin film encapsulation layer E is described below.

The emission portion may be formed on the first substrate 11. The emission portion may include a thin film transistor (TFT). A passivation layer 70 may be formed to cover the emission portion and the TFT. An organic light-emitting device 80 may be formed on the TFT and the passivation layer.

The first substrate 11 may include a glass material. However, the first substrate 11 is not limited to a glass material. The first substrate 11 may include a plastic material and a metallic material such as stainless steel and/or titanium (Ti). The first substrate 11 may include polyimide (PI). For convenience of description, the case where the first substrate 11 includes a glass material is described below.

A buffer layer 20 including an organic compound and/or an inorganic compound is further formed on the upper surface of the first substrate 11. The buffer layer 20 may include SiOx (x≧1) and SiNx (x≧1).

After an active layer 30 arranged in a predetermined pattern is formed on the buffer layer 20, the active layer 30 may be buried by a gate insulating layer 40. The active layer 30 may include a source region 31 and a drain region 33. The active layer 30 may also include a channel region 32 between the source region 31 and the drain region 33.

The active layer 30 may include various materials. For example, the active layer 30 may include an inorganic semiconductor material such as amorphous silicon or crystalline silicon. As another example, the active layer 30 may include an oxide semiconductor. As another example, the active layer 30 may include an organic semiconductor material. For convenience of description, the case where the active layer 30 includes amorphous silicon is described.

The active layer 30 may be formed by forming an amorphous silicon layer on the buffer layer 20, and then crystallizing the amorphous silicon layer to form a polycrystalline silicon layer, and then patterning the polycrystalline silicon layer. The active layer 30 may include the source region 31 and the drain region 33 doped with impurities depending on the kind of a TFT such as a driving TFT (not shown) and a switching TFT (not shown).

A gate electrode 50 corresponding to the active layer 30, and an interlayer insulating layer 60 burying the gate electrode 50 may be formed on the upper surface of the gate insulating layer 40.

A contact hole H1 may be formed in the interlayer insulating layer 60 and the gate insulating layer 40. After the contact hole H1 is formed, a source electrode 71 and a drain electrode 72 may be formed on the interlayer insulating layer 60 to contact the source region 31 and the drain region 33, respectively.

The passivation layer 70 may be formed above the TFT, and a pixel electrode 81 of an organic light-emitting device (OLED) may be formed above the passivation layer 70. The pixel electrode 81 may contact the drain electrode 72 of the TFT through a via hole H2 formed in the passivation layer 70.

The passivation layer 70 may include an inorganic material and/or an organic material, and include a single layer or two or more layers. The passivation layer 70 may be formed as a planarization layer so that its upper surface is flat regardless of bending of a lower layer, or may be formed to be bent depending on bending of a layer located below. Also, the passivation layer 70 may include a transparent insulating material to accomplish a resonance effect.

The pixel electrode 81 may be formed on the passivation layer 70. A pixel-defining layer 90 may include an organic material and/or an inorganic material to cover the pixel electrode 81 and the passivation layer 70. The pixel-defining layer 90 may include an opening to expose the pixel electrode 81.

An intermediate layer 82 and an opposite electrode 83 may be formed on at least the pixel electrode 81.

The pixel electrode 81 may serve as an anode electrode, and the opposite electrode 83 may serve as a cathode electrode. As understood by a person of ordinary skill in the art, the polarities of the pixel electrode 81 and the opposite electrode 83 may be reversed.

The pixel electrode 81 and the opposite electrode 83 may be insulated from each other by the intermediate layer 82. A voltage of a different polarity may be applied to the intermediate layer 82 to allow the organic emission layer to emit light.

The intermediate layer 82 may include an organic emission layer. The intermediate layer 82 may include an organic emission layer, as well as at least one of an HIL, an HTL, an ETL, and an EIL. However, exemplary embodiments are not limited to an intermediate layer 82 with these layer. The intermediate layer 82 may include various functional layers (not shown).

One unit pixel may include a plurality of sub-pixels. The plurality of sub-pixels may emit light of various colors. For example, the plurality of sub-pixels may include sub-pixels emitting light of red, green, and blue colors. The plurality of sub-pixels, may include sub-pixels emitting light of red, green, blue, and white colors.

The thin film encapsulation layer E may include a plurality of inorganic layers, organic layers, or an inorganic layer and an organic layer.

The organic layer of the thin film encapsulation layer E may include a polymer. The organic layer of the thin film encapsulation layer E may include a single layer or stacked layers including at least one of polyethylene terephthalate (PET), polyimide, polycarbonate, epoxy, polyethylene, and polyacrylate. For example, the organic layer of the thin film encapsulation layer E may include polyacrylate. The organic layer of the thin film encapsulation layer E may include a polymerized monomer composition including a diacrylate-based monomer and a triacrylate-based monomer. The monomer composition may further include a mono acrylate-based monomer. Also, the monomer composition may further include a well-known photoinitiator such as trimethyl benzoyl diphenyl phosphine oxide (TPO). However, exemplary embodiments are not limited to these materials or structures of organic layer of the thin film encapsulation layer.

The inorganic layer of the thin film encapsulation layer E may include a single layer or stacked layers. The inorganic layer of the thin film encapsulation layer E ma include a metallic oxide and/or a metallic nitride. The inorganic layer may include at least one of silicon nitride (SiNₓ), aluminum oxide (Al₂O₃), silicon dioxide (SiO₂), and titanium dioxide (TiO₂).

An uppermost layer of the thin film encapsulation layer E facing away from the first substrate 11 may be exposed to external elements (e.g., oxygen, nitrogen, moisture, dirt) and may include an inorganic layer in order to prevent penetration of moisture into the organic light-emitting device.

The thin film encapsulation layer E may include at least one sandwich structure in which at least one organic layer is inserted between at least two inorganic layers. For example, the thin film encapsulation layer E may include at least one sandwich structure in which at least one inorganic layer is inserted between at least two organic layers. As another example, the thin film encapsulation layer E may include a sandwich structure in which at least one organic layer is inserted between at least two inorganic layers and a sandwich structure in which at least one inorganic layer is inserted between at least two organic layers.

The thin film encapsulation layer E may include a first inorganic layer, a first organic layer, and a second inorganic layer sequentially from above the OLED.

As another example, the thin film encapsulation layer E may include a first inorganic layer, a first organic layer, a second inorganic layer, a second organic layer, and a third inorganic layer sequentially from above the OLED.

As another example, the thin film encapsulation layer E may include a first inorganic layer, a first organic layer, a second inorganic layer, a second organic layer, a third inorganic layer, a third organic layer, and a fourth inorganic layer sequentially from above the OLED.

A halogenated metallic layer including lithium fluoride (LiF) may be included between the OLED and the first inorganic layer. The halogenated metallic layer may prevent the OLED from being damaged when the first inorganic layer is formed by using a sputtering method.

The first organic layer may have an area narrower than that of the second inorganic layer. The second organic layer may have an area narrower than that of the third inorganic layer.

In the organic light-emitting display device 10, the intermediate layer 82, which is an organic layer, may be manufactured via the apparatus 1 for depositing the organic layer described with reference to FIGS. 1, 2, 3, 4, and 5.

Therefore, the organic light-emitting display device 10 may include the intermediate layer 82 having a fine pattern. Also, the organic light-emitting display device 10 has excellent emission performance, and a defective pixel may be minimized.

An organic light-emitting display device according to various exemplary embodiments may implement image quality of high density. An apparatus for depositing an organic layer and a method of manufacturing an organic light-emitting display device by using the same according to exemplary embodiments may improve productivity of a display panel, reduce manufacturing costs, and reduce a defect rate of a panel manufactured in a deposition process.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An apparatus for depositing an organic layer, comprising:
a deposition unit comprising a deposition assembly spaced apart from a substrate,
wherein the deposition assembly comprises:
a deposition source configured to heat a deposition material;
a deposition source nozzle unit installed on the deposition source, the deposition source nozzle unit comprising a deposition nozzle;
a plurality of pattern sheets facing the deposition source nozzle unit, the plurality of pattern sheets comprising at least one of a plurality of first patterning slits and a plurality of second patterning slits; and
a source shutter disposed between the deposition source and the plurality of pattern sheets, the source shutter configured to allow the deposition material to pass through one of the plurality of pattern sheets depending on a relative location between the deposition source and the substrate.

2. The apparatus of claim 1, wherein:
the plurality of pattern sheets are arranged on a same plane; and
the source shutter is configured to allow the deposition material be deposited on at least one of a first region and a second region of the substrate.

3. The apparatus of claim 1, wherein adjacent pattern sheets from among the plurality of pattern sheets are alternately disposed with respect to an arbitrary straight line parallel to a movement direction of the substrate that passes a space between the adjacent pattern sheets.

4. The apparatus of claim 1, wherein each of the plurality of first patterning slits are spaced apart at a first interval and each of the plurality of second patterning slits are spaced apart at a second interval that is identical or different from the first interval.

5. The apparatus of claim 1, wherein an area of a first region of the substrate is different from an area of a second region of the substrate.

6. The apparatus of claim 1, wherein:
the source shutter comprises a first shutter and a second shutter; and
the source shutter is configured to block or open a path from the deposition source depending on a relative movement of the first shutter and the second shutter.

7. A method of manufacturing an organic light-emitting display device, the method comprising:
fixing a substrate to a movement portion at a loading portion;
transferring the movement portion inside a chamber by using a first transfer portion installed to pass through the chamber;
heating a deposition material from a deposition source nozzle unit of a deposition assembly;
passing the heated deposition material through a pattern sheet opened by a source shutter;
depositing the deposition material on different regions of the substrate while the substrate moves relative to the deposition assembly that is disposed inside the chamber spaced;
separating the substrate having the deposition material from the movement portion at an unloading portion; and
transferring the movement portion to the loading portion by using a second transfer portion installed to pass through the chamber,
wherein the pattern sheet faces the deposition source nozzle unit and comprises:
at least one of a plurality of first patterning slits that allows the deposition material to pass to a first region from among the different regions of the substrate and a plurality of second patterning slits that allows the deposition material to pass to a second region from among the different regions of the substrate.

8. The method of claim 7, wherein the pattern sheet comprises a plurality of pattern sheets arranged on a same plane.

9. The method of claim 8, wherein adjacent pattern sheets adjacent among the plurality of pattern sheets are alternately disposed with respect to an arbitrary straight line parallel to a movement direction of the substrate.

10. The method of claim 7, wherein each of the plurality of first patterning slits are spaced apart at a first interval and each of the plurality of second patterning slits are spaced apart at a second interval that is identical or different from the first interval.

11. The method of claim 7, wherein an area of the first region of the substrate is different from an area of the second region of the substrate.

12. The method of claim 7, wherein:
the source shutter comprises a first shutter and a second shutter; and
the source shutter blocks or opens at least one of a first path from a deposition source to the first region of the substrate and a second path from the deposition source to the second region of the substrate depending on a relative movement of the first shutter and the second shutter.

13. The method of claim 12, wherein:
the source shutter sequentially opens the first path by moving at least one of the first shutter and second shutter and the second path by moving at least one of the first shutter and the second shutter.

14. An organic light-emitting display device, comprising:
a base substrate;
a thin film transistor disposed on the base substrate, the thin film transistor comprising a semiconductor active layer, a gate electrode insulated from the semiconductor active layer, a source electrode contacting the semiconductor active layer, and a drain electrode contacting the semiconductor active layer;
a plurality of pixel electrodes disposed on the thin film transistor;
a plurality of organic layers disposed on the plurality of pixel electrodes; and
a plurality of opposite electrodes disposed on the plurality of organic layers,
wherein at least one of the plurality of organic layers disposed on the base substrate is formed by using the apparatus of claim 1.
